(19) United States
(12) Patent Application Publication
(10) Pub. No.: US 2022/0132708 A1
(43) Pub. Date: Apr. 28, 2022

(54) SHIELD CASE

(71) Applicant: Mitsubishi Electric Corporation, Tokyo (JP)

(72) Inventors: Ryoto ADACHI, Tokyo (JP); Toshiyuki MORIBAYASHI, Tokyo (JP)

(73) Assignee: Mitsubishi Electric Corporation, Tokyo (JP)

(21) Appl. No.: 17/430,356

(22) PCT Filed: Mar. 28, 2019
(86) PCT No.: PCT/JP2019/013556

§ 371 Date: Aug. 12, 2021

(51) Int. Cl. H05K 9/00; H05K 1/11; H05K 1/02; H01Q 1/38; H05K 1/16

(52) U.S. Cl. CPC H05K 9/006; H05K 1/115; H05K 2201/10098; H01Q 1/38; H05K 1/16; H05K 1/0237

(57) ABSTRACT

Provided is a shield case, including: a case main body configured to cover at least a part of a circuit pattern provided on a mounting surface of a substrate; a flange portion extending from an outer peripheral end portion of the case main body in a direction of separating away from the case main body along the mounting surface; and a bent portion bending and extending from an outer peripheral end portion of the flange portion in a direction of separating away from the mounting surface, wherein the shield case is to be mounted to the substrate by means of a joining member to be provided between the flange portion and a case mounting region of the substrate at which the flange portion is to be arranged, and between the bent portion and the case mounting region.

### TECHNICAL FIELD

The present invention relates to a shield case to be mounted to a substrate.

### BACKGROUND ART

Hitherto, a shield case configured to shield an electronic component or a circuit pattern of a high-frequency circuit board is mounted to a ground pattern of the high-frequency circuit board. The shield case is mounted by applying solder between an outer peripheral end portion of the shield case and the ground pattern so as to achieve conduction between the shield case and the ground pattern (see, for example, Patent Literature 1).

### CITATION LIST

### Patent Literature

[PTL 1] JP 2013-46260 A

### SUMMARY OF INVENTION

### Technical Problem

When the related-art shield case is mounted to the ground pattern of the high-frequency circuit board, the solder or flux applied between the outer peripheral end portion of the shield case and the ground pattern may flow out of the ground pattern. There has been a problem in that the solder or the flux flowing out of the ground pattern adheres to an antenna pattern provided on the high-frequency circuit board, to thereby cause reduction in antenna performance.

The present invention has been made to solve the above-mentioned problem, and has an object to provide a shield case with which solder and flux can be prevented from flowing out of a case mounting region in a mounting surface of a substrate.

### Solution to Problem

According to the present invention, there is provided a shield case, including: a case main body configured to cover at least a part of a circuit pattern provided on a mounting surface of a substrate; a flange portion extending from an outer peripheral end portion of the case main body in a direction of separating away from the case main body along the mounting surface; and a bent portion bending and extending from an outer peripheral end portion of the flange portion in a direction of separating away from the mounting surface, wherein the shield case is to be mounted to the substrate by means of a joining member to be provided between the flange portion and a case mounting region of the substrate at which the flange portion is to be arranged, and between the bent portion and the case mounting region.

### Advantageous Effects of Invention

According to the shield case of the present invention, solder and flux can be prevented from flowing out of the case mounting region in the mounting surface of the substrate.

### BRIEF DESCRIPTION OF DRAWINGS

FIG. 1 is a perspective view for illustrating a high-frequency circuit board having mounted thereon a shield case according to a first embodiment of the present invention.

FIG. 2 is a partially omitted sectional view taken along the line II-II of FIG. 1.

FIG. 3 is a partially omitted sectional view for illustrating a state of solder and flux in a case in which a flange portion without a bent portion is mounted to a ground pattern.

FIG. 4 is a partially omitted sectional view for illustrating a first modification example of the shield case of the first embodiment.

FIG. 5 is a partially omitted sectional view for illustrating a second modification example of the shield case of the first embodiment.

FIG. 6 is a perspective view for illustrating a high-frequency circuit board having mounted thereon a shield case according to a second embodiment of the present invention.

FIG. 7 is a plan view for illustrating a part A of FIG. 6 in an enlarged manner.

FIG. 8 is a partially omitted sectional view taken along the line VIII-VIII of FIG. 6.

FIG. 9 is a perspective view for illustrating a high-frequency circuit board having mounted thereon a shield case according to a third embodiment of the present invention.

FIG. 10 is a partially omitted sectional view taken along the line X-X of FIG. 9.

### DESCRIPTION OF EMBODIMENTS

Now, embodiments of this invention are described with reference to the drawings.

### First Embodiment

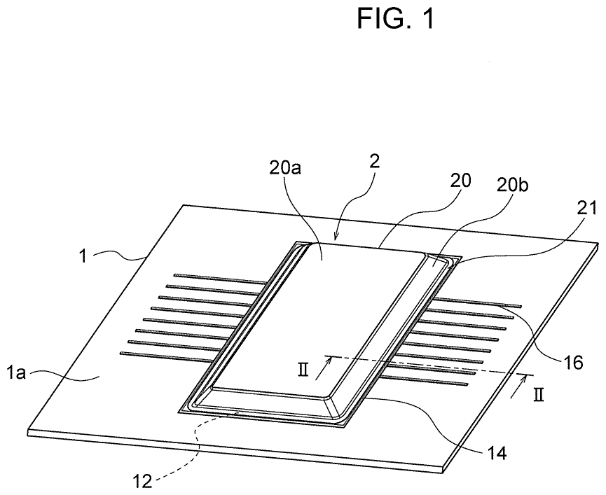

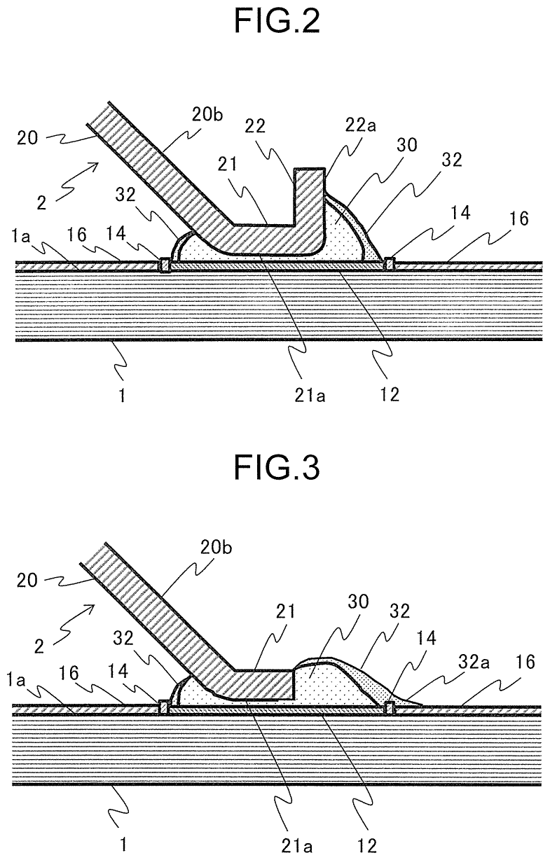

FIG. 1 is a perspective view for illustrating an example of a high-frequency circuit board 1 having mounted thereon a shield case 2 according to a first embodiment of the present invention. FIG. 2 is a sectional view taken along the line II-II of FIG. 1.

As illustrated in FIG. 1 and FIG. 2, on a mounting surface 1a of the high-frequency circuit board 1, a ground pattern 12, resist portions 14, and a plurality of antenna patterns 16 are provided. The antenna patterns 16 form at least a part of a circuit pattern formed on the mounting surface 1a.

The ground pattern 12 has an outer shape formed into a rectangular loop shape. The resist portions 14 are provided in a loop shape respectively along an outer periphery and an inner periphery of the ground pattern 12. The plurality of antenna patterns 16 are provided on an inner side and an outer side of the ground pattern 12. The antenna patterns 16 are each linearly formed, and are arranged at intervals. Each of the resist portions 14 is provided between the ground pattern 12 and the antenna patterns 16. The resist portions 14 project, from the mounting surface 1a, upward with respect to the ground pattern 12 and the antenna patterns 16.

The shield case 2 includes a case main body 20, a flange portion 21, and a bent portion 22. The shield case 2 has a shape of a turned-over rectangular tray.

The case main body 20 is arranged on the mounting surface 1a side of the high-frequency circuit board 1 so as to cover an upper side of at least a part of the circuit pattern formed on the mounting surface 1a. The case main body 20 includes a top plate 20a and an inclined surface 20b. The top plate 20a is formed into a rectangular flat-plate shape. The inclined surface 20b is inclined downward from an outer peripheral end portion of the top plate 20a toward the mounting surface 1a side of the high-frequency circuit board 1. With the case main body 20 being formed as described above, a space is defined between the top plate 20a of the case main body 20 and the circuit pattern formed on the mounting surface 1a.

A loop-shaped flange portion 21 is provided at an outer peripheral part of the inclined surface 20b. The flange portion 21 extends from an outer peripheral end portion of the inclined surface 20b in a direction of separating away from the case main body 20 along the mounting surface 1a of the high-frequency circuit board 1. The flange portion 21 has a joining surface 21a to be joined to the ground pattern 12 serving as a case mounting region.

The bent portion 22 formed into a loop shape is provided at an outer peripheral part of the flange portion 21. The bent portion 22 bends and extends from an outer peripheral end portion of the flange portion 21 in a direction of separating away from the mounting surface 1a. In the example of FIG. 2, the bent portion 22 extends in a direction perpendicular to the mounting surface 1a.

The shield case 2 is mounted to the high-frequency circuit board 1 by means of solder 30. The solder 30 serves as a joining member, and is to be provided between the flange portion 21 and the ground pattern 12 at which the flange portion 21 is to be arranged, and between the bent portion 22 and the ground pattern 12. As a result, the shield case 2 is electrically connected to the ground pattern 12 via the solder 30.

Now, an action and an effect of the bent portion 22 are described with reference to FIG. 2 and FIG. 3.

FIG. 3 is a sectional view for illustrating a state of the solder 30 and flux 32 in a case in which the flange portion 21 without the bent portion 22 is mounted to the ground pattern 12. When the bent portion 22 is not provided to the flange portion 21, the solder 30 and the flux 32 applied between the flange portion 21 and the ground pattern 12 do not bulge so much, and spread on the ground pattern 12. In this case, as a flow-out portion 32a illustrated in FIG. 3, the flux 32 may go over the resist portion 14 to cover a part of the antenna pattern 16.

In contrast, in a case in which, as the shield case 2 of the first embodiment illustrated in FIG. 2, the bent portion 22 is provided to the flange portion 21, the solder 30 applied between the bent portion 22 and the ground pattern 12 bulges along a wall surface 22a of the bent portion 22 due to the surface tension of the wall surface 22a. Thus, the solder 30 is prevented from spreading on the ground pattern 12 to cause the flux 32 to go over and flow out of the resist portion 14 for the ground pattern 12.

As described above, in the shield case 2 according to the first embodiment, the bent portion 22 is provided to the flange portion 21, and the shield case 2 is mounted to the high-frequency circuit board 1 by means of the solder 30 provided between the flange portion 21 and the ground pattern 12 at which the flange portion 21 is to be arranged, and between the bent portion 22 and the ground pattern 12.

Further, the solder 30 provided between the bent portion 22 and the ground pattern 12 is caused to bulge along the wall surface 22a. Accordingly, the solder 30 and the flux are prevented from going over the resist portion 14 and flowing out of the ground pattern 12. As a result, the antenna pattern 16 can be prevented from being covered with the flux 32, and the high-frequency circuit board 1 can be prevented from being reduced in antenna performance.

In the first embodiment, the shield case 2 has a rectangular outer shape. However, the outer shape of the shield case 2 is not limited thereto. For example, the outer shape of the shield case 2 may be an ellipse or a polygon, for example, a hexagon.

Further, in the first embodiment, the case main body 20 includes the flat plate-shaped top plate 20a and the inclined surface 20b. However, the configuration of the case main body 20 is not limited thereto. For example, the entire inclined surface 20b or a part of the inclined surface 20b may be formed of a curved surface so that the top plate 20a and the flange portion 21 are connected to each other by the curved surface. Further, the top plate 20a and the inclined surface 20b may be formed of a curved surface as a whole. In this case, the case main body 20 is not required to have the inclined surface 20b.

Further, in the shield case 2 according to the first embodiment, the bent portion 22 is formed to extend perpendicularly to the mounting surface 1a in the direction of separating away from the mounting surface 1a. However, the shape of the bent portion 22 is not limited thereto.

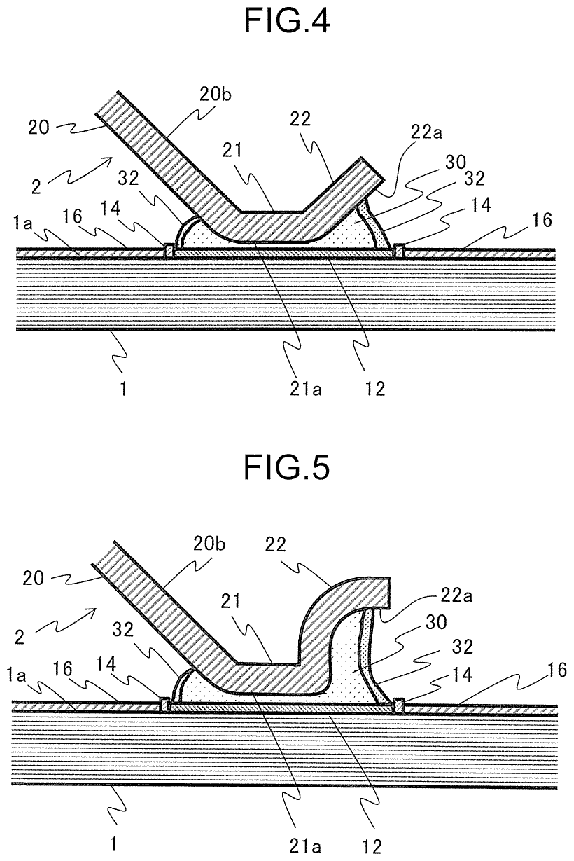

FIG. 4 is a sectional view for illustrating a first modification example of the shield case 2 of the first embodiment. In the first modification example, the bent portion 22 extends in the direction of separating away from the mounting surface 1a while inclining at an angle smaller than 90° with respect to the mounting surface 1a. Even with the first modification example, an effect similar to that of the shield case 2 of the first embodiment can be obtained.

Further, FIG. 5 is a sectional view for illustrating a second modification example of the shield case 2 of the first embodiment. In the second modification example, the bent portion is formed, similarly to the bent portion 22 in the first embodiment, from the outer peripheral end portion of the flange portion 21 to extend perpendicularly to the mounting surface 1a in the direction of separating away from the mounting surface 1a. In the second modification example, the bent portion 22 further bends and extends along the mounting surface 1a in a direction of separating away from the flange portion 21. Even with the second modification example, an effect similar to that of the shield case 2 of the first embodiment can be obtained.

### Second Embodiment

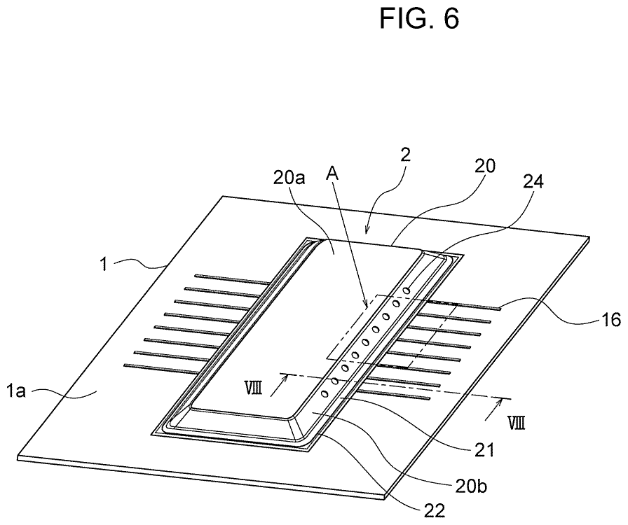

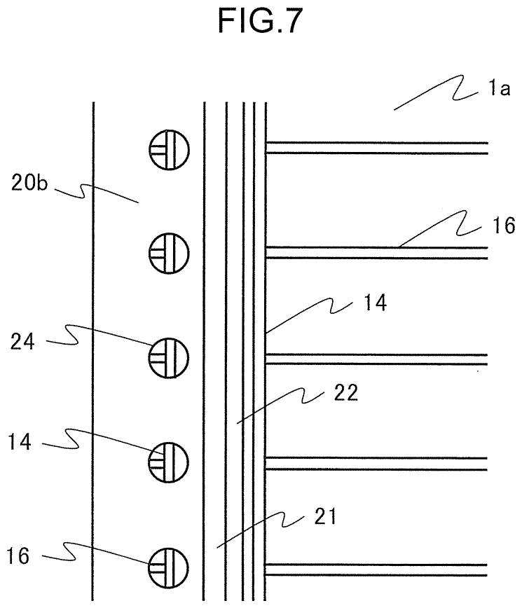

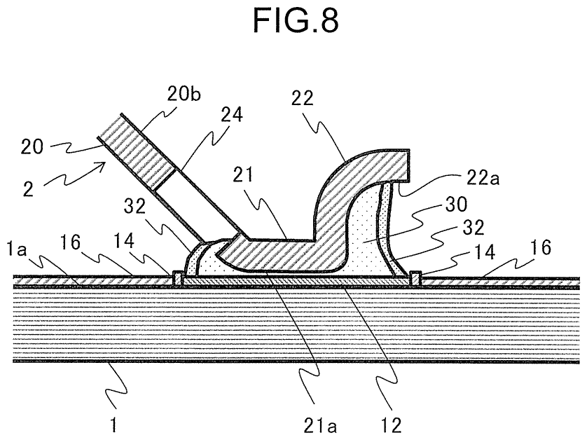

FIG. 6 is a perspective view for illustrating a high-frequency circuit board 1 having mounted thereon a shield case 2 according to a second embodiment of the present invention. FIG. 7 is a plan view for illustrating a part A of FIG. 6 in an enlarged manner. FIG. 8 is a sectional view taken along the line VIII-VIII of FIG. 6.

The shield case 2 according to the second embodiment is different from that of the first embodiment in the shape of the case main body 20. Other configurations are similar to those of the first embodiment.

As illustrated in FIG. 6 to FIG. 8, in the shield case 2 according to the second embodiment, the inclined surface 20b of the case main body 20 has a plurality of through holes 24.

In the shield case 2 according to the second embodiment, the plurality of through holes 24 are formed in the inclined surface 20b so that heat generated from the circuit pattern or an electronic component in the shield case 2 can be released through the through holes 24.

Further, each through hole 24 has a diameter that is set so as to be equal to or smaller than ¼ of a wavelength of a high-frequency wave to be generated from the circuit pattern of the high-frequency circuit board 1. This setting is made in order to prevent the high-frequency wave from passing through the shield case 2 via the through holes 24.

As illustrated in FIG. 8, the through hole 24 is formed in a region of the inclined surface 20b close to the flange portion 21. Thus, the solder 30 and the flux 32 are also applied to the inside of the through hole 24. In this manner, an area in which the flange portion 21 and the ground pattern 12 are joined to each other is increased. Accordingly, a joining strength between the shield case 2 and the ground pattern 12 can be increased.

Each through hole 24 may be formed above the antenna pattern 16 covered with the case main body 20. In this case, whether or not the solder 30 and the flux 32 have flowed onto the antenna pattern 16 can be visually checked through each through hole 24.

### Third Embodiment

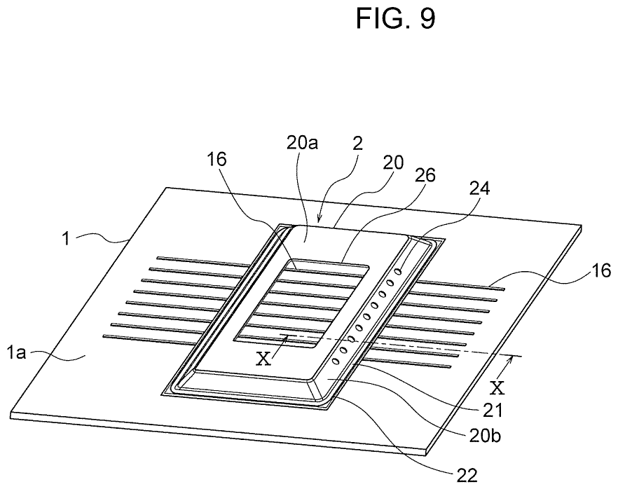

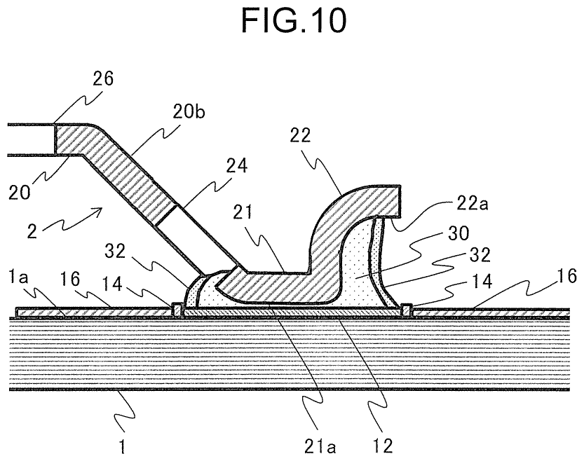

FIG. 9 is a perspective view for illustrating a high-frequency circuit board 1 having mounted thereon a shield case 2 according to a third embodiment of the present invention. FIG. 10 is a sectional view taken along the line X-X of FIG. 9.

The shield case 2 according to the third embodiment is different from that of the second embodiment in that the case main body 20 has an opening portion 26. Other configurations are similar to those of the second embodiment.

In the case main body 20 of the shield case 2, the rectangular opening portion 26 is formed in the vicinity of the center of the top plate 20a. This opening portion 26 is closed by a conductive member, for example, a conductive tape, after the shield case 2 is mounted to the high-frequency circuit board 1.

In the shield case 2 according to the third embodiment, the opening portion 26 is formed in the case main body 20 so that, even after the shield case 2 is mounted to the high-frequency circuit board 1, a state of the mounting surface 1a covered with the case main body 20 can be checked through the opening portion 26. Therefore, whether or not the solder 30 or the flux 32 has adhered on the antenna pattern 16 covered with the case main body 20 can be checked after the shield case 2 is mounted.

Further, after the shield case 2 is mounted, even when the solder 30 or the flux 32 has adhered to the antenna pattern 16, the solder 30 or the flux 32 adhering to the antenna pattern 16 can be removed through the opening portion 26.

In the shield case 2 of the third embodiment, the opening portion 26 has a rectangular shape. However, the shape of the opening portion 26 is not limited thereto. For example, the shape of the opening portion 26 may be an ellipse or a polygon, for example, a hexagon. Further, the opening portion 26 may be divided into two or more opening portions.

### REFERENCE SIGNS LIST

1 high-frequency circuit board (substrate), 2 shield case, 12 ground pattern (case mounting region), 14 resist portion, 16 antenna pattern (circuit pattern), 20 case main body, 20a top plate, 20b inclined surface, 21 flange portion, 21a joining surface, 22 bent portion, 22a wall surface, 24 through hole, 26 opening portion, 30 solder (joining member), 32 flux.

1-8: (canceled)

9: A shield case, comprising:
a case main body configured to cover at least a part of a circuit pattern provided on a mounting surface of a substrate;
a flange portion extending from an outer peripheral end portion of the case main body in a direction of separating away from the case main body along the mounting surface; and
a bent portion bending and extending from an outer peripheral end portion of the flange portion in a direction of separating away from the mounting surface,
wherein the shield case is to be mounted to the substrate by means of a joining member to be provided between the flange portion and a case mounting region of the substrate at which the flange portion is to be arranged, and between the bent portion and the case mounting region.

10: The shield case according to claim 9, wherein the bent portion further bends and extends along the mounting surface in a direction of separating away from the flange portion.

11: The shield case according to claim 9,
wherein the case main body includes, in an outer peripheral part thereof, an inclined surface inclined downward from a center side of the case main body toward the flange portion, and
wherein the inclined surface has at least one through hole.

12: The shield case according to claim 10,
wherein the case main body includes, in an outer peripheral part thereof, an inclined surface inclined downward from a center side of the case main body toward the flange portion, and
wherein the inclined surface has at least one through hole.

13: The shield case according to claim 11,
wherein the substrate is a high-frequency circuit board, and
wherein the at least one through hole has a diameter that is equal to or smaller than ¼ of a wavelength of a high-frequency wave to be generated from the circuit pattern.

14: The shield case according to claim 12,
wherein the substrate is a high-frequency circuit board, and
wherein the at least one through hole has a diameter that is equal to or smaller than ¼ of a wavelength of a high-frequency wave to be generated from the circuit pattern.

15: The shield case according to claim 11, wherein the at least one through hole is formed in the inclined surface on a side close to the flange portion.

16: The shield case according to claim 12, wherein the at least one through hole is formed in the inclined surface on a side close to the flange portion.

17: The shield case according to claim 13,
wherein the circuit pattern includes an antenna pattern, and
wherein the at least one through hole is formed above the antenna pattern.

18: The shield case according to claim 14,
wherein the circuit pattern includes an antenna pattern, and
wherein the at least one through hole is formed above the antenna pattern.

19: The shield case according to claim 9, wherein the case main body has an opening portion formed in a vicinity of a center of the case main body.

20: The shield case according to claim 19, wherein a conductive member configured to close the opening portion is mountable to the opening portion.
